(19) United States
(12) Patent Application Publication
(10) Pub. No.: US 2014/0176232 A1
(43) Pub. Date: Jun. 26, 2014

(54) CARTESIAN FEEDBACK LOOP TRANSMITTER WITH IMPROVED LOOP FILTER

(71) Applicant: Christoph Maximilian STEINBRECHER, Flemington, NJ (US)

(72) Inventor: Christoph Maximilian STEINBRECHER, Flemington, NJ (US)

(73) Assignee: Analog Devices, Inc., Norwood, MA (US)

(21) Appl. No.: 13/725,375

(22) Filed: Dec. 21, 2012

(51) Int. Cl. H03B 1/00

(52) U.S. Cl. CPC H03B 1/00
USPC 327/553; 327/552

(57) ABSTRACT

A filter may include multiple circuit sub-systems, where one circuit sub-system may have an output connected to an input of another circuit sub-system. Each circuit sub-system may include an amplifier with an output connected to the output of the circuit sub-system. Each circuit sub-system may include a first network connecting an input of the circuit sub-system to a first reference input of the amplifier, and a second network connecting the output of the amplifier to the first reference input of the amplifier. The filter may include a link network connecting the output of one circuit sub-system to an input of another circuit sub-system.

### BACKGROUND

Non-linearity or distortions, in power amplifiers (PA) is generally undesirable. The PA may generate distortions, such as 3rd-order inter-modulation (IM3) adjacent to the signal band. These distortions may degrade adjacent channel leakage ratio (ACLR) performance.

There may be tradeoffs between the efficiency of a PA and its linearity. Either the efficiency is good and the linearity is poor, or the linearity is good and the efficiency is poor. Low efficiency is undesirable, because it may lead to large power consumption, excessive heating of the PA module, and/or short battery life.

The PA in a radio-frequency (RF) transmission system may use feedback circuit paths, for example Cartesian feedback loops with loop filters, to suppress signal distortions, and to improve the linearity of the PA without sacrificing PA efficiency. The loop filter may generate a large amount of signal gain while suppressing the distortion generated by the PA.

Delays in the PA may cause phase shift, and may result in instability of signals in the PA. To stabilize the feedback circuit path, the unity gain frequency (UGF) may need to be lowered. If the UGF approaches the bandwidth of the signal to be transmitted, very little suppression of the distortion is achieved. There may be a direct tradeoff between the UGF of the feedback loop and the PA delay in determining the desired stability margin. If a large signal bandwidth is desired, the transition region between the ACLR region and the UGF becomes very small, and an effective improvement of ACLR may become difficult.

Therefore, there may be a need to improve the ACLR caused by distortion components directly adjacent to the signal bandwidth, and to improve linearity of the RF transmission system.

### BRIEF DESCRIPTION OF THE DRAWINGS

FIG. 1 illustrates a filter according to an embodiment of the present disclosure.

FIG. 2 illustrates another filter according to an embodiment of the present disclosure.

FIG. 3 illustrates a system with a filter according to an embodiment of the present disclosure.

FIG. 4 illustrates a plot of simulated distortion transfer function (DTF) frequency-gain characteristics of a filter according to an embodiment of the present disclosure.

### DETAILED DESCRIPTION

According to the embodiments of the present disclosure, a filter may include multiple circuit sub-systems, where one circuit sub-system may have an output connected to an input of another circuit sub-system. Each circuit sub-system may include an amplifier with an output connected to the output of the circuit sub-system. Each circuit sub-system may include a first network connecting an input of the circuit sub-system to a first reference input of the amplifier, and a second network connecting the output of the amplifier to the first reference input of the amplifier. The filter may include a link network connecting the output of one circuit sub-system to an input of another circuit sub-system.

According to the embodiments of the present disclosure, a system may include a filter with an output connected to a coupling network. The coupling network generates a feedback signal connected to an input of the filter. The filter may include multiple circuit sub-systems, where one circuit sub-system may have an output connected to an input of another circuit sub-system. Each circuit sub-system may include an amplifier with an output connected to the output of the circuit sub-system. Each circuit sub-system may include a first network connecting an input of the circuit sub-system to a first reference input of the amplifier, and a second network connecting the output of the amplifier to the first reference input of the amplifier. The filter may include a link network connecting the output of one circuit sub-system to an input of another circuit sub-system.

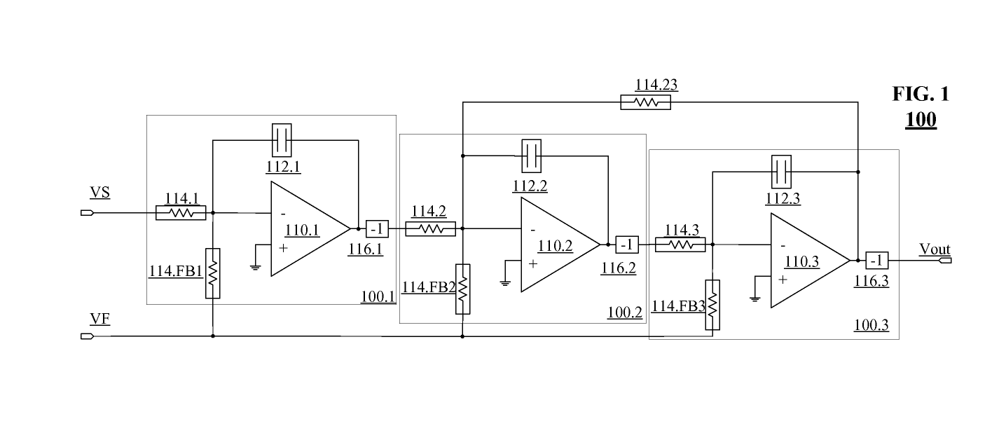

FIG. 1 illustrates a filter according to an embodiment of the present disclosure.

According to an embodiment of the present disclosure, a filter 100 may include multiple circuit sub-systems 100.1 to 100.3, where one circuit sub-system may have an output connected to an input of another circuit sub-system. For example, the output of sub-system 100.1 may be connected to the input of sub-system 100.2, and the output of 100.2 may be connected to the input of sub-system 100.3.

Each circuit sub-system may include an amplifier (respectively, 110.1 to 110.3), a first network (respectively, 114.1 to 114.3), and a second network (respectively, 112.1 to 112.3). For example, sub-system 100.1 may include an amplifier 110.1, a first network 114.1, and a second network 112.1.

According to an embodiment of the present disclosure, as an non-limiting example, the circuit sub-system 100.1 may have the amplifier 110.1 with an output connected to the output of the circuit sub-system 100.1. The circuit sub-system 100.1 may have the first network 114.1 connecting an input of the circuit sub-system to a first reference input of the amplifier 110.1, and the second network 112.1 connecting the output of the amplifier 110.1 to the first reference input of the amplifier 110.1.

According to an embodiment of the present disclosure, other circuit sub-systems may be similarly configured.

According to an embodiment of the present disclosure, as an non-limiting example, the filter 100 may include a link network 114.23 connecting the output of one circuit sub-system 100.3 to an input of another circuit sub-system 100.2. According to an embodiment, the link network 114.23 may be connected to the input of another circuit sub-system 100.2 at a reference input of amplifier 110.2 of the circuit sub-system 100.2.

According to an embodiment of the present disclosure, the first network (respectively, 114.1 to 114.3) may include a resistance network. A resistance network may include pure resistive elements, active transistor-type resistive elements, digitally tunable resistors, etc.

According to an embodiment of the present disclosure, the second network (respectively, 112.1 to 112.3) may include a capacitance network. A capacitance network may include pure capacitance elements, digitally tunable capacitors, etc.

According to an embodiment of the present disclosure, the first network (respectively, 114.1 to 114.3) and the second network (respectively, 112.1 to 112.3) may be programmable, or may be tuned, to allow adjustment of frequency-gain characteristics of the filter 100.

According to an embodiment of the present disclosure, each circuit sub-system may include a third network (respectively, 114.FB1 to 114.FB3) connecting a feedback signal VF to the reference input of the amplifier (respectively, 110.1 to 110.3) of the circuit sub-system.

According to an embodiment of the present disclosure, the third network (respectively, 114.FB1 to 114.FB3) may include a resistance network, a transconductance cell, a capacitance network, and/or a demodulator.

According to an embodiment of the present disclosure, each circuit sub-system may include an inverting network (respectively, 116.1 to 116.3) connecting the output of the amplifier (respectively, 110.1 to 110.3) to the output of the circuit sub-system (respectively, 100.1 to 100.3). The inverting network may invert the output of one circuit sub-system and send the inverted output to the input of another circuit sub-system.

According to an embodiment of the present disclosure, multiple circuit sub-systems may form two or more parallel circuit paths of cascading circuit sub-systems (not shown), wherein one path may be connected to another path via a crossing network (not shown). The crossing network may include a resistance network and/or a capacitance network.

According to an embodiment of the present disclosure, the filter 100 may include cascade of two or more circuit sub-systems (100.1 to 100.3). The circuit sub-systems (100.1 to 100.3) may be integrators.

The link network 114.23 may be a local resistive feedback across a cascade of any two circuit sub-systems (integrators), to implement a band-pass resonator, i.e. a narrowband region with high loop gain. According to an embodiment of the present disclosure, more than two resonators (not shown) may be implemented using additional circuit sub-systems (integrators).

According to an embodiment of the present disclosure, multiple parallel cascading filter paths may be implemented, and cross-coupling between the parallel filter paths may be possible.

According to an embodiment of the present disclosure, the internal feedback loop may be realized by connecting a link network 114.23 from the output of one circuit sub-system 100.3 to an input of another circuit sub-system 100.2.

According to an embodiment of the present disclosure, the feedback resistors 114.FB1 to 114.FB3 may be implemented as active Gm-stages, or the feedback signals may be supplied directly from multiple demodulators in a feedback path, (for example, I/Q demodulators), as long as they may be capable of providing sufficient signal current into each stage of cascading circuit sub-systems.

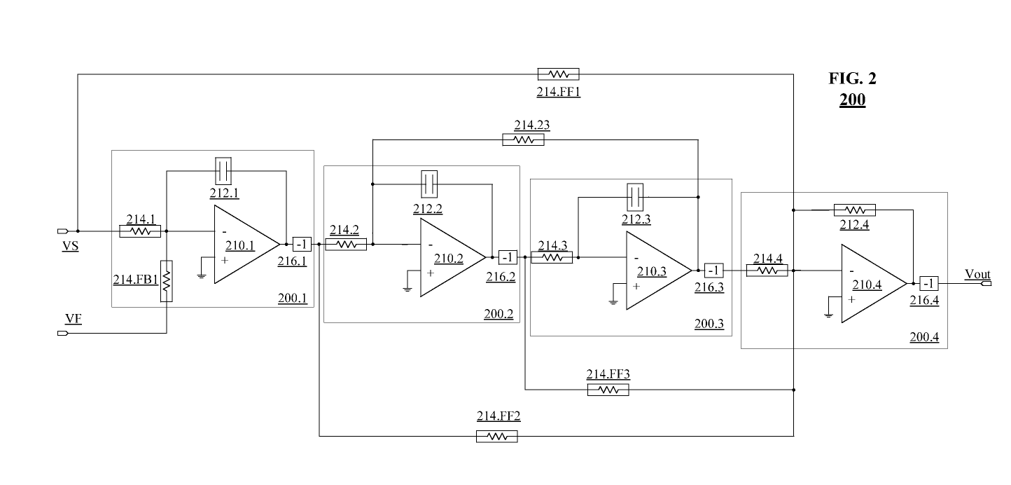

FIG. 2 illustrates another filter according to an embodiment of the present disclosure.

According to an embodiment of the present disclosure, a filter 200 may include multiple circuit sub-systems 200.1 to 200.4, where one circuit sub-system may have an output connected to an input of another circuit sub-system. For example, the output of sub-system 200.1 may be connected to the input of sub-system 200.2, and the output of 200.2 may be connected to the input of sub-system 200.3, etc.

Each circuit sub-system may include an amplifier (respectively, 210.1 to 210.4), a first network (respectively, 214.1 to 214.4), and a second network (respectively, 212.1 to 212.4). For example, sub-system 200.1 may include an amplifier 210.1, a first network 214.1, and a second network 212.1.

According to an embodiment of the present disclosure, as an non-limiting example, the circuit sub-system 200.1 may have the amplifier 210.1 with an output connected to the output of the circuit sub-system 200.1. The circuit sub-system 200.1 may have the first network 214.1 connecting an input of the circuit sub-system to a first reference input of the amplifier 210.1, and the second network 212.1 connecting the output of the amplifier 210.1 to the first reference input of the amplifier 210.1.

According to an embodiment of the present disclosure, other circuit sub-systems may be similarly configured.

According to an embodiment of the present disclosure, as a non-limiting example, the filter 200 may include a link network 214.23 connecting the output of one circuit sub-system 200.3 to an input of another circuit sub-system 200.2. According to an embodiment, the link network 214.23 may be connected to the input of another circuit sub-system 200.2 at a reference input of amplifier 210.2 of the circuit sub-system 200.2.

According to an embodiment of the present disclosure, the first network (respectively, 214.1 to 214.4) may include a resistance network. A resistance network may include pure resistive elements, active transistor-type resistive elements, digitally tunable resistors, etc.

According to an embodiment of the present disclosure, the second network (respectively, 212.1 to 212.4) may include a capacitance network or a resistive network. A capacitance network may include pure capacitance elements, digitally tunable capacitors, etc. As illustrated in FIG. 2, the circuit sub-system 200.4 in the last stage may be configured as a summing amplifier with two resistive networks 212.4 and 214.4.

According to an embodiment of the present disclosure, the first network (respectively, 214.1 to 214.4) and the second network (respectively, 212.1 to 212.4) may be programmable, or may be tuned, to allow adjustment of frequency-gain characteristics of the filter 200.

According to an embodiment of the present disclosure, a circuit sub-system 200.1 may include a third network 214.FB1 connecting a feedback signal VF to the reference input of the amplifier 210.1 of the circuit sub-system.

According to an embodiment of the present disclosure, the third network 214.FB1 may include a resistance network, a transconductance cell, a capacitance network, and/or a demodulator.

According to an embodiment of the present disclosure, each circuit sub-system may include an inverting network (respectively, 216.1 to 216.4) connecting the output of the amplifier (respectively, 210.1 to 210.4) to the output of the circuit sub-system (respectively, 200.1 to 200.4). The inverting network may invert the output of one circuit sub-system and send the inverted output to the input of another circuit sub-system.

According to an embodiment of the present disclosure, the input of one circuit sub-system 200.1 may be connected via a forwarding network 214.FF1 to the reference input of the amplifier 210.4 of another circuit sub-system 200.4, which may be connected to the output of the circuit sub-system 200.1. In an embodiment, the circuit sub-system 200.4 may be connected in series with circuit sub-systems 200.2 and 200.3 to the output of the circuit sub-system 200.1. According to an embodiment of the present disclosure, the input of one circuit sub-system 200.2 may be connected via a forwarding network 214.FF2 to the reference input of the amplifier 210.4 of another circuit sub-system 200.4. According to an embodiment of the present disclosure, the input of one circuit sub-system 200.3 may be connected via a forwarding network 214.FF3 to the reference input of the amplifier 210.4 of another circuit sub-system 200.4.

According to an embodiment of the present disclosure, the forwarding networks (respectively, 214.FF1 to 214.FF3) may each include a resistance network. A resistance network may include pure resistive elements, active transistor-type resistive elements, digitally tunable resistors, etc.

According to an embodiment of the present disclosure, multiple circuit sub-systems may form two or more parallel circuit paths of cascading circuit sub-systems (not shown), wherein one path may be connected to another path via a crossing network (not shown). The crossing network may include a resistance network and/or a capacitance network.

According to an embodiment of the present disclosure, the filter 200 may have only one feedback point, for example at VF via feedback network 214.FB1 at circuit sub-system 200.1. This configuration may be feasible for specific design requirements. For example, input signals VS and VF may be current signals, consequently feedback network 214.FB1 need not include any resistive network, and signal VF may be effectively fed directly to the reference input of amplifier 210.1 of the circuit subsystem 200.1. In this configuration, multiple forwarding networks (respectively, 214.FF1 to 214.FF3) may be used, to feed forward signals from each circuit sub-system to the input of the last stage sub-system 200.4, which sums all of the feed-forward signals.

The feed-forward path from the first stage sub-system 200.1 to the amplifier 210.4 of the last stage sub-system 200.4 via 214.FF1 may cause the STF of the filter 200 to be unity (0 dB) for all frequencies.

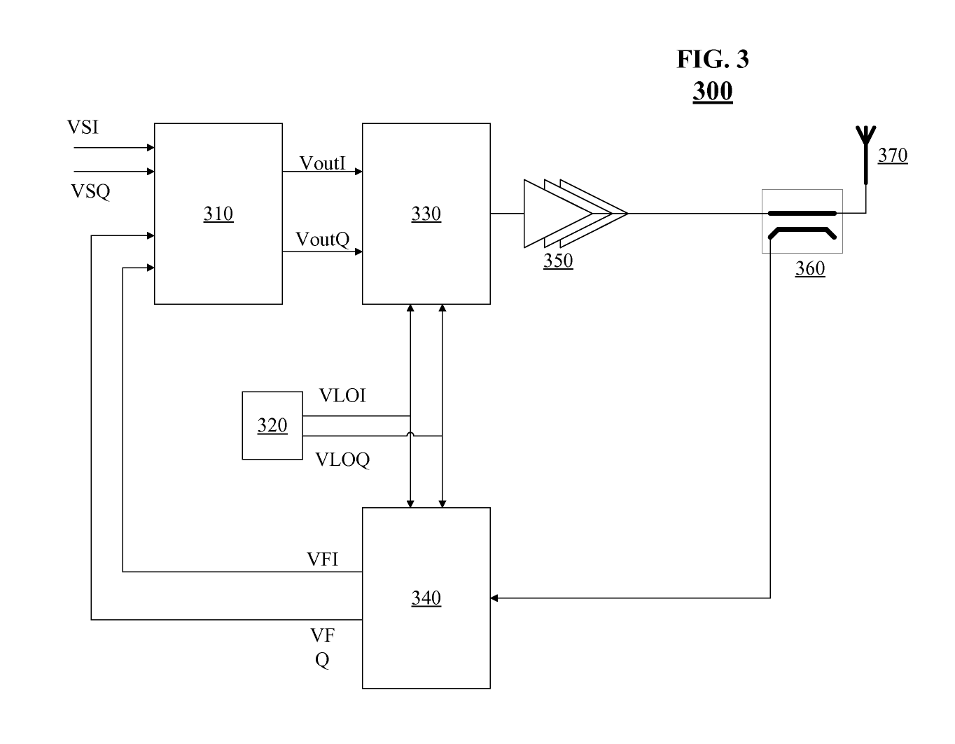

FIG. 3 illustrates a system with a filter according to an embodiment of the present disclosure.

According to the embodiments of the present disclosure, a system 300 may include a filter 310 with an output connected to a coupling network 360. The coupling network 360 generates a feedback signal connected to an input of the filter 310.

According to the embodiments of the present disclosure, the filter 310 may include a filter similar to filter 100 in FIG. 1, or the filter 200 in FIG. 2.

According to the embodiments of the present disclosure, the system 300 may include a modulator 330 that may modulate baseband I/Q signals into RF signal, a PA stage 350 that may amplify the RF signal for transmission at antenna 370, a I/Q demodulator 340 that may receive the feedback signal from coupling network 360 and demodulate the feedback signal into feedback baseband signals, and a local oscillator (LO) 320 that may control the modulator 330 and demodulator 340.

According to the embodiments of the present disclosure, the system 300 may be a Cartesian feedback loop that may improve the linearity of PA in the transmission of RF signals. The forward path in the system may include the filter 310, the modulator 330, and the PA stage 350. The feedback path may include the demodulator 340 (and may include an attenuator, not shown). The LO 320 may include a I/Q generator (not shown) and a phase shifter (not shown).

The complex baseband input signals VSI and VSQ may be applied to one set of inputs of the filter 310. The feedback signals VFI and VFQ are applied to another set of inputs of the filter 310. The output of the filter 310, may be sent to the modulator 330, which may modulate and convert the signal into RF signal, which may be amplified by the PA stage 350.

The PA stage 350 may be a significant source of non-linearity in the system 300.

The signal delivered to the antenna 370 may be coupled through a coupling network 360 to generate a feedback signal. The demodulator 340 (along with an attenuator) may attenuate the feedback signal and demodulate the feedback signal to generate baseband feedback signals VFI and VFQ.

The LO 320 may generate the modulation/demodulation signals VLOI and VLOQ for the secondary inputs of the modulator 330 and the demodulator 340. An I/Q generator (not shown) may shift the signals from each other by 90 degrees to synthesize the modulation/demodulation signals VLOI and VLOQ. The modulation/demodulation signals VLOI and VLOQ may pass through a phase shifter (shown) before being applied to the demodulator 340.

The forward gain of a filter, i.e. gain of VoutI/VSI or VoutQ/VSQ, may be represented by L₀(S), and the feedback gain, i.e. gain of VoutI/VFI or VoutQ/VFQ, may be represented by L₁(S).

The signal transfer function (STF) for the system 300 may be represented by

$$STF = \frac{{L}_{0} ( s ) {K}_{U}}{1 + {K}_{1} ( s ) {K}_{U} {K}_{D}} ,$$

where Kᵤ may represent the total gain of the forward path of the system 300 divided by L₀(S), which may be the total gain from the output of the filter 310 to the output at the PA stage 350. K_{D} may represent the total gain of the feedback path of the system 300, which may include the coupling network 360 and the demodulator 340. The STF may represent the total gain from VSI and VSQ to the output at the antenna 370.

Also, the distortion transfer function (DTF) for the system 300 may be represented by

$$DTF = \frac{1}{1 + {L}_{1} ( s ) {K}_{U} {K}_{D}} .$$

The DTF may represent the total gain of PA distortion signals at the antenna 370. The DTF may be generally smaller than one, which may indicate that distortion of the PA is suppressed. To decrease the DTF to be much smaller than one, it may be helpful to maximize L1(s).

The forward gain L₀(S) according to the embodiments of the present disclosure, as illustrated in FIGS. 1-3, may be represented as:

$${L}_{0} ( s ) = \frac{1}{1 + {R}_{23} {C}_{2} {R}_{3} {C}_{3} {s}^{2}} \cdot \frac{1}{{R}_{1} {C}_{1} \frac{{R}_{2}}{{R}_{23}} s} ,$$

where R₂₃ may represent the resistance value of the link network 114.23 and 214.23, (R₁, R₂, R₃) may represent the resistance values of the respective first networks (114.1-114.3, or 214.1-214.3), (C₁, C₂, C₃) may represent the capacitance values of the respective second networks (112.1-112.3, or 212.1-212.3), and S may represent the input signal frequency.

The feedback gain L₁(S)according to the embodiments of the present disclosure, as illustrated in FIGS. 1-3, may be represented as:

$${L}_{1} ( s ) = \frac{1}{1 + {R}_{23} {C}_{2} {R}_{3} {C}_{3} {s}^{2}} \cdot \frac{1 + \frac{{R}_{FB 1}}{{R}_{FB 2}} {R}_{2} {C}_{1} s + \frac{{R}_{FB 1}}{{R}_{FB 3}} {R}_{2} {R}_{3} {C}_{1} {C}_{2} {s}^{2}}{{R}_{FB 1} {C}_{1} \frac{{R}_{2}}{{R}_{23}} s} ,$$

where R_{FB1}, R_{FB2}, and R_{FB3} may represent the resistance values of the respective third networks (114.FB1-114.FB3).

The STF according to the embodiments of the present disclosure, as illustrated in FIGS. 1-3, may be represented as:

$$STF = \frac{{R}_{FB 1}}{{R}_{1} {K}_{D}} \cdot \frac{1}{\begin{matrix}1 + ( \frac{1}{{R}_{FB 2}} + \frac{1}{{R}_{23} {K}_{U} {K}_{D}} ) {R}_{FB 1} {R}_{2} {C}_{1} s + \\ \frac{{R}_{FB 1}}{{R}_{FB 3}} {R}_{2} {R}_{3} {C}_{2} {C}_{3} {s}^{2} + \frac{{R}_{FB 1} {R}_{2} {R}_{3} {C}_{1} {C}_{2} {C}_{3}}{{K}_{U} {K}_{D}} {s}^{3}\end{matrix}} .$$

The poles of the STF (denominator of the second term) may be configured in various embodiments to have particular responses, (for example, Butterworth, Chebyshev, or polynomial type filter responses). At low frequencies, the second term's value may approach one, and thus the DC gain of the system 300 may be represented as R_{FB1}/R₁/K_{D}.

The DTF according to the embodiments of the present disclosure, as illustrated in FIGS. 1-3, may be represented as:

$$DTF = ( 1 + {R}_{23} {C}_{2} {R}_{3} {C}_{3} {s}^{2} ) \cdot \frac{{R}_{2}}{{R}_{23}} \frac{{R}_{FB1} {C}_{1} s}{{K}_{U} {K}_{D}} \cdot \\ \frac{1}{\begin{matrix}1 + ( \frac{1}{{R}_{FB2}} + \frac{1}{{R}_{23} {K}_{U} {K}_{D}} ) {R}_{FB1} {R}_{2} {C}_{1} s + \frac{{R}_{FB1}}{{R}_{FB3}} {R}_{2} {R}_{3} {C}_{2} {C}_{3} {s}^{2} + \\ \frac{{R}_{FB1} {R}_{2} {R}_{3} {C}_{1} {C}_{2} {C}_{3}}{{K}_{U} {K}_{D}} {s}^{3}\end{matrix}} .$$

The first term, (1+R₂₃C₂R₃C₃S²), may approach a complex zero at angular frequency 1/(R₂₃C₂R₃C₃), due to the local resonator, and may improve ACLR of the filter 310 and the system 300, according to the embodiments of the present disclosure.

The second term,

$$\frac{{R}_{2}}{{R}_{23}} \frac{{R}_{FB 1} {C}_{1} s}{{K}_{U} {K}_{D}} ,$$

may represent distortion suppression at low frequencies. The linking network 114.23 and 214.23 with resistance value R₂₃ may further contribute to distortion suppression in the second term. The third term may represent the same zero poles as represented in the STF.

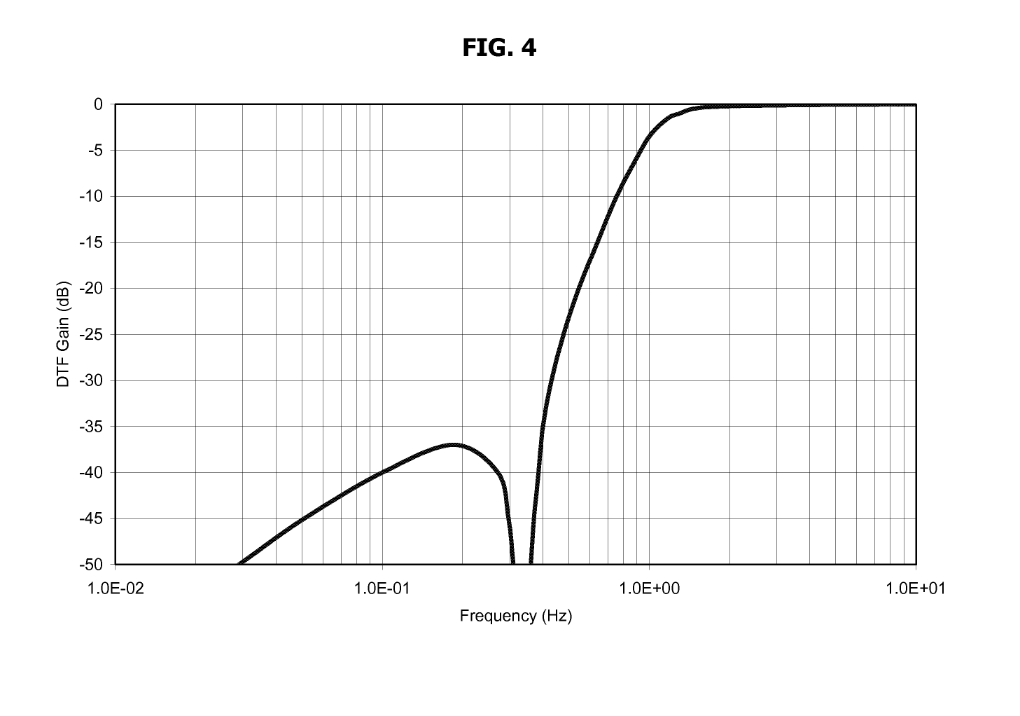

FIG. 4 illustrates a plot of simulated DTF frequency-gain characteristics of a system according to an embodiment of the present disclosure.

As exemplarily illustrated in FIG. 4, the system's DTF gain may be near 0 dB (or gain of 1) between 1 Hz and 10 Hz, but may decrease significantly from 1 Hz to 0.35 Hz. Near 0.35 Hz, the DTF gain may approach −∞ dB (or gain of 0), due to the first term, (1+R₂₃C₂R₃C₃S²), as illustrated above. Below 0.35 Hz, the DTF gain may be largely determine by the second term,

$$\frac{{R}_{2}}{{R}_{23}} \frac{{R}_{FB 1} {C}_{1} s}{{K}_{U} {K}_{D}} .$$

Accordingly, the system's DTF gain characteristics may have improved linearity and ACLR performance, to suppress distortions in the system.

1. A filter comprising:
a plurality of circuit sub-systems, including a first circuit sub-system and a second circuit sub-system, wherein the first circuit sub-system having an output connected to an input of the second circuit sub-system; and
a link network connecting an output of the second circuit sub-system to connect a feedback directly and only to an input of the first circuit sub-system;
wherein each circuit sub-system of the plurality of circuit sub-systems includes:
an amplifier with an output connected to an output of the circuit sub-system;
a first network connecting an input of the circuit sub-system to a reference input of the amplifier; and
a second network connecting the output of the amplifier to the reference input of the amplifier.

2. The filter of claim 1, wherein the first network comprises a resistance network.

3. The filter of claim 1, wherein the second network comprises a capacitance network.

4. The filter of claim 1, wherein the first network and the second network are programmable.

5. The filter of claim 1, wherein at least one circuit sub-system further comprises a third network connecting a feedback signal to the reference input of the amplifier of the circuit sub-system.

6. The filter of claim 5, wherein the third network comprises at least one of a resistance network, a transconductance cell, a capacitance network, and a demodulator.

7. The filter of claim 1, wherein the input of the first circuit sub-system is connected via a forwarding network to the reference input of the amplifier of another circuit sub-system connected to the output of the first circuit sub-system.

8. The filter of claim 7, wherein the forwarding network is a resistance network.

9. The filter of claim 1, wherein the plurality of the circuit sub-systems form at least two paths, wherein one path is connected to another path via a crossing network.

10. The filter of claim 9, wherein the crossing network comprises at least one of a resistance network and a capacitance network.

11. A system comprising:
a coupling network; and
a filter having an output connected to the coupling network, the coupling network generating a feedback signal connected to an input of the filter;
wherein the filter includes:
a plurality of circuit sub-systems, including a first circuit sub-system and a second circuit sub-system, wherein the first circuit sub-system having an output connected to an input of the second circuit sub-system; and
a link network connecting an output of the second circuit sub-system to connect a feedback directly and only to an input of the first circuit sub-system;
wherein each circuit sub-system of the plurality of circuit sub-systems includes:
an amplifier with an output connected to an output of the circuit sub-system;
a first network connecting an input of the circuit sub-system to a reference input of the amplifier; and
a second network connecting the output of the amplifier to the reference input of the amplifier.

12. The system of claim 11, wherein the first network comprises a resistance network.

13. The system of claim 11, wherein the second network comprises a capacitance network.

14. The system of claim 11, wherein the first network and the second network are programmable.

15. The system of claim 11, wherein at least one circuit sub-system further comprises a third network connecting the feedback signal to the reference input of the amplifier of the circuit sub-system.

16. The system of claim 15, wherein the third network comprises at least one of a resistance network, a transconductance cell, a capacitance network, and a demodulator.

17. The system of claim 11, wherein the input of the first circuit sub-system is connected via a forwarding network to the reference input of the amplifier of another circuit sub-system connected to the output of the first circuit sub-system.

18. The system of claim 17, wherein the forwarding network is a resistance network.

19. The system of claim 11, wherein the plurality of the circuit sub-systems form at least two paths, wherein one path is connected to another path via a crossing network.

20. The system of claim 19, wherein the crossing network comprises at least one of a resistance network and a capacitance network.
